(19) United States
(12) Patent Application Publication
(10) Pub. No.: US 2025/0105612 A1
(43) Pub. Date: Mar. 27, 2025

(54) DC ARC SIGNAL GENERATION CIRCUIT, DC ARC DETECTION DEVICE AND ELECTRICAL DEVICE

(71) Applicant: Xiamen Ampack Technology Limited, Xiamen (CN)

(72) Inventors: Wenji HUANG, Xiamen (CN); Qifan LIU, Xiamen (CN)

(73) Assignee: Xiamen Ampack Technology Limited, Xiamen (CN)

(21) Appl. No.: 18/895,745

(22) Filed: Sep. 25, 2024

(30) Foreign Application Priority Data
Sep. 26, 2023 (CN) 202311253371.6

(51) Int. Cl. H02H 1/00; H03B 5/26

(52) U.S. Cl. CPC H02H 1/0015; H03B 5/26

(57) ABSTRACT

A DC arc signal generation circuit comprises: a first power supply, a first switch unit, and a Wien bridge oscillator circuit, and the Wien bridge oscillator circuit includes an operational amplifier. The first power supply is electrically connected to a positive input terminal and a power supply terminal of the operational amplifier respectively through the first switch unit. The Wien bridge oscillator circuit is configured to output a DC arc detection signal in response to turn-on of the first switch unit.

### CROSS-REFERENCE TO RELATED APPLICATION

This application claims priority from Chinese Patent Application No. 202311253371.6, filed on Sep. 26, 2023, the content of which is incorporated herein by reference in its entirety.

### TECHNICAL FIELD

Embodiments of this application relate to the field of electronic power technology, and in particular to a DC arc signal generation circuit, a DC arc detection device and an electrical device.

### BACKGROUND

With the development of photovoltaic power generation, especially the popularity of distributed photovoltaic power generation, higher and higher requirements have been placed on the safety of photovoltaic power stations. There are many electrical connection points in a photovoltaic power generation system, and a DC voltage of the photovoltaic power generation system is getting higher and higher. If there is a poor connection at a connection point, arcing will occur. Because the photovoltaic system is DC power, and there is no zero crossing point, once this kind of arc burns, it is not easy to be extinguished and will cause serious harm. It may burn electrical equipment, and even it may cause a fire. Therefore, timely detection of arc phenomena is crucial to avoid arc hazards and ensure that electrical device is not damaged.

### SUMMARY

Embodiments of this application provide a DC arc signal generation circuit, a DC arc detection device and an electrical device. The DC arc signal generation circuit can output a DC arc detection signal and apply the DC arc detection signal to the DC arc detection device, so as to implement arc detection.

In a first aspect, embodiments of this application provide a DC arc signal generation circuit. The DC arc signal generation circuit includes: a first power supply, a first switch unit, and a Wien bridge oscillation circuit. The Wien bridge oscillator circuit includes an operational amplifier. The first power supply is electrically connected to a positive input terminal and a power supply terminal of the operational amplifier respectively through the first switch unit. The Wien bridge oscillator circuit is configured to output a DC arc detection signal in response to turn-on of the first switch unit.

In these embodiments, the DC arc signal generation circuit can output a DC arc detection signal, and apply the DC arc detection signal to a DC arc detection device to implement arc detection.

In some embodiments, the DC arc signal generation circuit further includes a controller, the first switch unit includes a first resistor and a first switch; a first terminal of the first resistor is connected to the controller and a first terminal of the first switch respectively. A second terminal of the first resistor is connected to the first power supply and a second terminal of the first switch respectively, and a third terminal of the first switch is connected to the Wien bridge oscillator circuit; and/or, the first switch unit includes a key switch, a first terminal of the key switch is connected to the first power supply, and a second terminal of the key switch is connected to the Wien bridge oscillator circuit.

In these embodiments, by providing the controller, the first resistor and the first switch, and/or providing the key switch, software and/or manual control of the Wien bridge oscillator circuit to output the DC arc detection signal can be achieved.

In some embodiments, the first switch unit further includes an OR gate. Where the first switch unit includes a first resistor, a first switch and a key switch. The second terminal of the key switch is connected to a first input terminal of the OR gate, and the third terminal of the first switch is connected to a second input terminal of the OR gate, and an output terminal of the OR gate is connected to the Wien bridge oscillator circuit.

In these embodiments, by providing the OR gate, normal operation of the circuit can be ensured when both the first switch and the key switch are provided.

In some embodiments, the Wien bridge oscillator circuit includes a frequency selection network and a second resistor, and the frequency selection network includes a third resistor and a first capacitor. A first terminal of the second resistor is connected to the first switch unit, and a second terminal of the second resistor is connected to a first terminal of the third resistor, a first terminal of the first capacitor, and a positive input terminal of the operational amplifier respectively. The third resistor is connected in parallel with the first capacitor, and a second terminal of the third resistor is connected to a second terminal of the first capacitor and then grounded.

In these embodiments, by providing the frequency selection network, the lower cutoff frequency of the DC arc detection signal can be adjusted, and the second resistor and the third resistor form a voltage dividing circuit to adjust the voltage amplitude of the DC arc detection signal.

In some embodiments, the DC arc signal generation circuit further includes a demultiplexer. An output terminal of the Wien bridge oscillator circuit is connected to the demultiplexer.

In these embodiments, by providing the demultiplexer, the DC arc detection signals can be subsequently output to different detection circuits, so that the different detection circuits can complete the arc self-detection at the same time.

In some embodiments, the DC arc signal generation circuit further includes a current conversion branch. The current conversion branch includes a second switch unit, and the output terminal of the Wien bridge oscillator circuit is electrically connected to the second switch unit. The current conversion branch is configured to output a current signal in response to turn-on of the second switch unit.

In these embodiments, by providing the current conversion branch, the DC arc detection signal is converted into a current signal and then input to the corresponding detection circuit for self-detection.

In some embodiments, the current conversion branch includes a second switch, a fourth resistor, a fifth resistor, a current transformer, and a second power supply. The current conversion branch provides a first current path, the second switch, the fourth resistor and the second power supply are disposed on the first current path, and the first current path also passes through the current transformer. A first terminal of the fifth resistor is connected to an output terminal of the operational amplifier and a control terminal of the second switch respectively, and one terminal of the second switch is connected to a second terminal of the fifth resistor and then grounded.

In these embodiments, the first current path can pass through a plurality of current transformers, so that the DC arc detection signals can be output to different detection circuits, so that the different detection circuits can complete the arc self-detections at the same time.

In a second aspect, embodiments of this application also provide a DC arc detection device, which includes a detection circuit and the DC arc signal generation circuit as in any embodiment of the first aspect. The DC arc signal generation circuit is connected to the detection circuit. The detection circuit is configured to detect DC arc in response to an electrical signal output by the DC arc signal generation circuit. In these embodiments, the DC arc signal generation circuit can output the DC arc detection signal to the detection circuit, so that the DC arc detection device has a self-detection function.

In some embodiments, the detection circuit includes a signal amplifying unit, a filtering unit and a signal processing unit. The signal amplifying unit is connected to the demultiplexer, or the signal amplifying unit is connected to the current conversion branch. The filtering unit is connected to the signal amplifying unit, and the signal processing unit is connected to the filtering unit. In these embodiments, by providing the signal amplifying unit, the filtering unit and the signal processing unit to process the DC arc detection signal, the self-detection work can be ensured.

In a third aspect, embodiments of this application further provide electrical device, which includes the DC arc detection device described in any embodiment of the second aspect. In these embodiments, the DC arc signal generation circuit can output a DC arc detection signal to the detection circuit, so that the electrical equipment has a self-detection function.

Compared with the prior art, the beneficial effects of this application are: different from the prior art, this application provides a DC arc signal generation circuit, a DC arc detection device and electrical device, including: a first power supply, a first switch unit and a Wien bridge oscillator circuit. The Wien bridge oscillator circuit includes an operational amplifier. Where the first power supply is electrically connected to a positive input terminal and a power supply terminal of the operational amplifier respectively through the first switch unit. The Wien bridge oscillator circuit is configured to output a DC arc detection signal in response to turn-on of the first switch unit. Where the DC arc signal generation circuit can output a DC arc detection signal, and subsequent application in a DC arc detection device can cause the DC arc detection signal to be output to the detection circuit to realize the self-detection function.

### BRIEF DESCRIPTION OF DRAWINGS

One or more embodiments are illustrated through the figures in the corresponding drawings. These exemplary illustrations do not constitute limitations to the embodiments. Elements/modules and steps with the same reference numerals in the drawings represent for similar elements/modules and steps. The figures in the drawings are not to be construed as limiting the scale unless otherwise stated.

FIG. 1 is a structural block diagram of a DC arc signal generation circuit provided by an embodiment of this application;

FIG. 2 is a schematic structural diagram of a DC arc signal generation circuit provided by an embodiment of this application; and

FIG. 3 is a schematic structural diagram of a detection circuit provided by an embodiment of this application.

### DETAILED DESCRIPTION

This application will be described in detail below with reference to specific embodiments. The following embodiments will help those skilled in the art further understand this application, but do not limit this application in any form. In order to facilitate understanding of this application, this application will be described in more detail below in conjunction with the accompanying drawings and specific embodiments.

Unless otherwise defined, all technical and scientific terms used in the description shall have the same meanings as commonly understood by a person skilled in the technical field to which this application belongs. The terms used in the description of this application are merely intended to describe the specific embodiments but not to limit this application. The term “and/or” used in the description includes any and all combinations of one or more of the relevant listed items.

It should be noted that, if there is no conflict, various features in the embodiments of this application can be combined with each other, and they are all within the protection scope of this application. In addition, although the functional modules are divided in the schematic diagram of the apparatus, in some cases, the module division can be different from that in the apparatus. In addition, the words “first”, “second” and other words used in the description do not limit the data and execution order, but only distinguish the same or similar items with basically same functions and effects.

At present, in DC arc detection circuits, a PWM signal generated by software is usually used to simulate the arc signal for self-detection work. However, it needs to rely on software to generate PWM signals, and the circuit stability is poor. Or, a noise generating circuit mainly using voltage regulator tubes generates noises for self-detection, but the frequency of the noises generated by using voltage regulator tubes is unstable, making it impossible to determine whether the signal transmission in the frequency domain is accurate, and it is necessary to add a first level signal filter, which increases costs.

In addition, the above two self-detection methods have relatively single functions. They can only complete self-detection work and cannot determine the fault location. Based on this, embodiments of this application provide a DC arc signal generation circuit, a DC arc detection device and electrical device. The DC arc signal generation circuit can output a DC arc detection signal, which can be subsequently used in the DC arc detection device. The DC arc detection signal can be output to the detection circuit to realize the self-detection function. In addition, it outputs the DC arc detection signal based on the Wien bridge oscillator circuit, which can improve the stability of the DC arc detection signal and reduce costs.

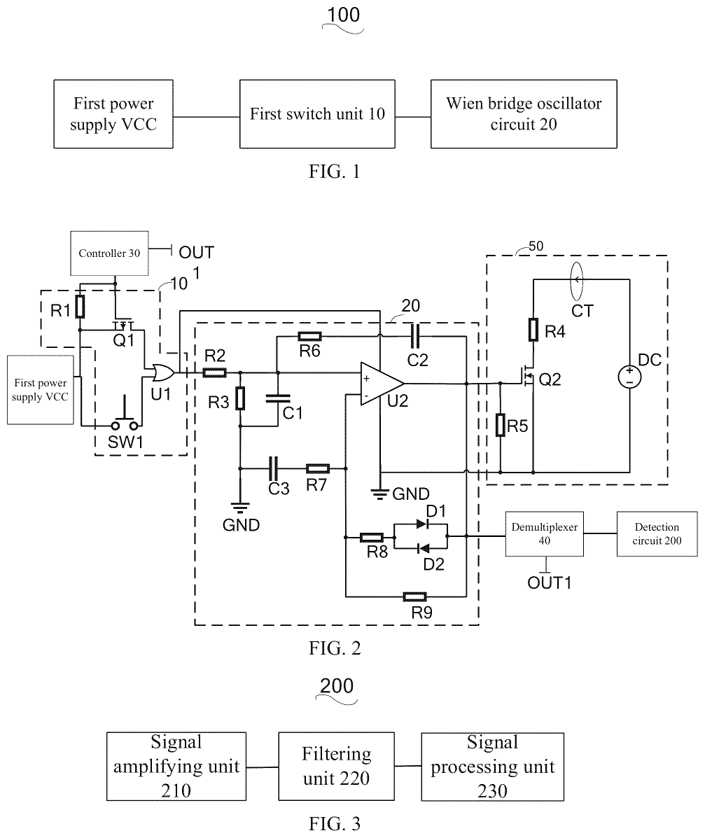

In a first aspect, embodiments of this application provide a DC arc signal generation circuit. Referring to FIG. 1, a DC arc signal generation circuit 100 includes: a first power supply VCC, a first switch unit 10, and a Wien bridge oscillator circuit 20. Referring to FIG. 2, the Wien bridge oscillator circuit 20 includes an operational amplifier U2. The first power supply VCC is electrically connected to the positive input terminal and the power supply terminal of the operational amplifier U2 through the first switch unit 10. The Wien bridge oscillator circuit 20 is configured to output a DC arc detection signal in response to turn-on of the first switch unit 10 being. In some embodiments of this application, the DC arc detection signal may be characterized as a voltage signal.

In the DC arc signal generation circuit 100, if the first switch unit 10 is turned on, the first power supply VCC outputs electric energy to the Wien bridge oscillator circuit 20, the Wien bridge oscillator circuit generates a sinusoidal signal of fixed frequency and amplitude based on the first power supply VCC, i.e., the DC arc detection signal, and the detection circuit in the DC arc detection device can detect the DC arc based on the DC arc detection signal. If the first switch unit 10 is turned off, the first power supply VCC cannot output electric energy to the Wien bridge oscillator circuit 20, and the Wien bridge oscillator circuit 20 does not output the DC arc detection signal.

In the DC arc signal generation circuit 100 provided by this application, the DC arc detection signal can be provided based on the Wien bridge oscillator circuit 20, and the DC arc detection signal can be applied to the DC arc detection device to realize self-detection function. In addition, the Wien bridge oscillator circuit 20 has stable oscillation and good output waveform, which can improve the stability of the DC arc detection signal, and the frequency of the DC arc detection signal output by it is adjustable. Moreover, using the Wien bridge oscillator circuit 20 to generate the DC arc detection signal to simulate the DC arc situation that occurs in the photovoltaic inverter is better than using the controller to output the DC arc detection signal to simulate the DC arc situation that occurs in the photovoltaic inverter, which can reduce costs.

In some embodiments, referring to FIG. 2, the DC arc signal generation circuit 100 further includes a controller 30, and the first switch unit 10 includes a first resistor R1 and a first switch Q1. A first terminal of the first resistor R1 is connected to the controller 30 and a first terminal of the first switch Q1 respectively. A second terminal of the first resistor R1 is connected to the first power supply VCC and a second terminal of the first switch Q1 respectively. A third terminal of the first switch Q1 is connected to the Wien bridge oscillator circuit 20; and/or the first switch unit 10 includes a key switch SW1, a first terminal of the key switch SW1 is connected to the first power supply VCC, and a second terminal of the key switch SW1 is connected to the Wien bridge oscillator circuit 20.

The controller 30 can be a single-chip microcomputer, and its specific model can be set according to actual needs, and is not limited here. Specifically, in the embodiments shown in FIG. 2, the first switch Q1 can be a PMOS tube, the first terminal of the first switch Q1 is the gate of the PMOS tube, the second terminal of the first switch Q1 is the source of the PMOS tube, and the third terminal of the first switch Q1 is the drain of the PMOS tube. The controller 30 outputs a low level signal to the first terminal of the first switch Q1, the first switch Q1 is turned on, and the first power supply VCC can output electric energy to the Wien bridge oscillation circuit 20 through the first switch Q1; the controller 30 outputs a high level signal to the first terminal of the first switch Q1, the first switch Q1 is turned off, and the first power supply VCC cannot output electric energy to the Wien bridge oscillation circuit 20 through the first switch Q1. In addition, the first resistor R1 can be used to prevent the first switch Q1 from malfunctioning due to the influence of noise signals, making the first switch Q1 cut off more reliably. For example, when the output signal of the controller 30 is uncertain, the first terminal of the first switch Q1 is connected to the first power supply VCC through the first resistor R1, that is, the first terminal of the first switch Q1 is at a high level, causing the first switch Q1 to be turned off, thereby preventing the circuit from being turned on by mistake and improving the reliability and security of the DC arc signal generation circuit 100. In practical applications, the first switch Q1 may be a PNP transistor or other types of switching apparatus, and there is no need to be limited to these embodiments.

If the key switch SW1 is pressed, the key switch SW1 is turned on, and the first power supply VCC can output electric energy to the Wien bridge oscillator circuit 20 through the key switch SW1; if the key switch SW1 is not pressed, the key switch SW1 is turned off, and the first power supply VCC cannot output electric energy to the Wien bridge oscillator circuit 20 through the key switch SW1, the first power supply VCC cannot output electric energy to the Wien bridge oscillator circuit 20 through the key switch SW1.

It can be seen that in these embodiments, by setting the controller 30, the first resistor R1 and the first switch Q1, the connection between the first power supply VCC and the Wien bridge oscillator circuit 20 can be established or broken through software control, so as to control whether the Wien bridge oscillator circuit 20 outputs a DC arc detection signal and realize whether the circuit performs self-detection work through software control, and/or, by setting the key switch SW1, manual control can be realized to establish or break the connection between the first power supply VCC and the Wien the bridge oscillator circuits 20, so as to control whether the Wien bridge oscillator circuit 20 generates a DC arc detection signal and realize whether the circuit performs self-detection work through manual control.

In some embodiments, referring to FIG. 2 again, the first switch unit 10 further includes an OR gate U1. The first switch unit 10 includes the first resistor R1, the first switch Q1 and the key switch SW1. The second terminal of the key switch SW1 is connected to a first input terminal of the OR gate U1, the third terminal of the first switch Q1 is connected to a second input terminal of the OR gate U1, and an output terminal of the OR gate U1 is connected to the Wien bridge oscillator circuit 20.

It can be understood that if the key switch SW1 is turned on, the first input terminal is at a high level, and if the first switch Q1 is turned on, the second input terminal is at a high level. The OR gate U1 is also known as OR circuit, logic and circuit. If at least one input terminal of the OR gate U1 is at a high level, the output terminal is at a high level. If all input terminals of the OR gate U1 are at a low level, then the output terminal is at a low level. Correspondingly, when the key switch SW1 is turned on and/or the first switch Q1 is turned on, the first power supply VCC will output a high level to the Wien bridge oscillator circuit 20 through the OR gate U1, and the Wien bridge oscillator circuit 20 will generate a DC arc detection signal based on the first power supply VCC. When the key switch SW1 is turned off and the first switch Q1 is turned off, the first power supply VCC will not be able to output a high level to the Wien bridge oscillation circuit 20 through the OR gate U1, and the bridge oscillator circuit 20 will not output a DC arc detection signal.

It can be seen that in these embodiments, by setting the OR gate U1, the normal operation of the circuit can be ensured when the first switch Q1 and the key switch SW1 are both provided. In these embodiments, a manual self-detection function and a software self-detection function are set simultaneously to improve the reliability of circuit operation.

In some embodiments, referring to FIG. 2, the Wien bridge oscillator circuit 20 includes a frequency selection network and a second resistor R2. The frequency selection network includes a third resistor R3 and a first capacitor C1. A first terminal of the second resistor R2 is connected to the first switch unit 10, and a second terminal of the second resistor R2 is connected to a first terminal of the third resistor R3, a first terminal of the first capacitor C1, and a positive input terminal of the operational amplifier U2 respectively. The third resistor R3 is connected in parallel with the first capacitor C1, and a second terminal of the third resistor R3 is connected to a second terminal of the first capacitor C1 and then grounded.

In the Wien bridge oscillator circuit 20, the third resistor R3 and the first capacitor C1 constitute a low-pass filter in the Wien bridge oscillator circuit 20. By adjusting the parameters of the third resistor R3 and the first capacitor C1, the lower cutoff frequency of the DC arc detection signal can be adjusted. In addition, the third resistor R3 and the second resistor R2 constitute a voltage dividing circuit. Optionally, the resistance of the third resistor R3 can be equal to the resistance of the second resistor R2. Then, the voltage input to the positive input terminal of the operational amplifier U2 is V/2, where V is the voltage value of the first power supply VCC. Therefore, the voltage amplitude of the DC arc detection signal can be adjusted by adjusting the resistances of the third resistor R3 and the second resistor R2.

In some embodiments, referring to FIG. 2, the frequency selection network also includes a sixth resistor R6 and a second capacitor C2. A first terminal of the sixth resistor R6 is connected to the positive input terminal of the operational amplifier U2, a second terminal of the sixth resistor R6 is connected to a first terminal of the second capacitor C2, and a second terminal of the second capacitor C2 is connected to an output terminal of the operational amplifier U2.

In the Wien bridge oscillator circuit 20, the sixth resistor R6 and the second capacitor C2 constitute a high-pass filter in the Wien bridge oscillator circuit 20. The upper cutoff frequency of the DC arc detection signal can be adjusted by adjusting the parameters of the sixth resistor R6 and the second capacitor C2. In this circuit, when the Wien bridge oscillator circuit 20 is first powered on, that is, when it first receives the first power supply VCC, it starts to oscillate. The disturbance components containing multiple frequencies will be amplified by the operational amplifier U2, and are then reduced when passing through the frequency selection network, so that the components of a specific frequency can stably oscillate and output. It can be seen that by setting the frequency selection network, the frequency range of the DC arc detection signal can be adjusted.

In some embodiments, referring to FIG. 2, the Wien bridge oscillator circuit 20 further includes: a seventh resistor R7, an eighth resistor R8, a ninth resistor R9, a third capacitor C3, a first diode D1 and a second diode D2. A first terminal of the third capacitor C3 is connected to the second terminal of the third resistor R3 and the second terminal of the first capacitor C1 respectively. A second terminal of the third capacitor C3 is connected to a first terminal of the seventh resistor R7. A second terminal of the seventh resistor R7 is connected to a negative input terminal of the operational amplifier U2, a first terminal of the eighth resistor R8 and a first terminal of the ninth resistor R9 respectively. A second terminal of the eighth resistor R8 is connected to an anode of the first diode D1 and a cathode of the second diode D2 respectively. A cathode of the first diode D1, an anode of the second diode D2 and a second terminal of the ninth resistor R9 are connected to the output terminal of the operational amplifier U2 respectively.

In the Wien bridge oscillator circuit 20, the first power supply VCC outputs electric energy to the Wien bridge oscillator circuit 20. In the initial stage, neither the first diode D1 nor the second diode D2 is conductive, and the amplification factor obtained by superposing the positive feedback coefficient and the negative feedback coefficient of the operational amplifier U2 is greater than 1. As the signal amplitude output by the operational amplifier U2 increases, both the first diode D1 and the second diode D2 are conductive, causing the eighth resistor R8 and the ninth resistor are connected in parallel to increase the negative feedback coefficient, thereby making the amplification coefficient less than 1 and reducing the signal amplitude output by the operational amplifier U2. In this way, the voltage amplitude of the signal output by the operational amplifier U2 can be stabilized at Vf+V/2, where V is the voltage value of the first power supply VCC, and Vf is the forward voltage of the diode.

It can be seen that in the Wien bridge oscillator circuit 20, the seventh resistor R7, the eighth resistor R8, the ninth resistor R9, the third capacitor C3, the first diode D1 and the second diode D2 in the Wien bridge oscillator circuit 20 can be used to constitute a negative feedback and amplification coefficient adjustment unit, and the stability of the voltage amplitude of the output signal can be improved in combination with positive feedback. In addition, in this circuit, the third capacitor C3 is used for DC blocking, so that the amplifier only amplifies the AC quantity.

In some embodiments, referring to FIG. 2, the DC arc signal generation circuit 100 further includes a demultiplexer 40. An output terminal of the Wien bridge oscillator circuit 20 is connected to the demultiplexer 40.

The demultiplexer 40 has a plurality of output terminals. The output terminal of the Wien bridge oscillator circuit 20 is connected to an input terminal of the demultiplexer 40. The control terminal of the demultiplexer 40 can be connected to the controller 30. The demultiplexer 40 can establish the connection between the input terminal and at least one output terminal based on the control signal of the controller 30, so that the at least one output terminal outputs a DC arc detection signal.

In the DC arc signal generation circuit 100, by setting the demultiplexer 40, the subsequent output terminal of the demultiplexer 40 can be connected to the detection circuit 200. Specifically, one output terminal is connected to one detection circuit 200. In this way, the DC arc detection signals can be output to different detection circuits 200, so that the different detection circuits 200 can complete the arc self-detections at the same time.

In some embodiments, referring to FIG. 2, the DC arc signal generation circuit 100 further includes a current conversion branch 50. The current conversion branch 50 includes a second switch unit, and the output terminal of the Wien bridge oscillator circuit 20 is electrically connected to the second switch unit. The current conversion branch 50 is configured to output a current signal in response to turn-on of the second switch unit.

In the DC arc signal generation circuit 100, the DC arc detection signal (voltage signal) output by the Wien bridge oscillator circuit 20 can be converted into a current signal through the above current conversation branch 50, then the current signal is output to the detection circuit, and the detection circuit performs arc detection based on the current signal.

In some embodiments, referring to FIG. 2 again, the current conversion branch 50 includes a second switch Q2, a fourth resistor R4, a fifth resistor R5, a current transformer CT, and a second power supply DC. The current conversion branch 50 provides a first current path. The second switch Q2, the fourth resistor R4 and the second power supply DC are located on the first current path. The first current path may also pass through the current transformer CT. A first terminal of the fifth resistor R5 is connected to the output terminal of the operational amplifier U2 and a control terminal of the second switch Q2 respectively. A second terminal of the second switch Q2 are connected to a second terminal of the fifth resistor R5 and then grounded.

In the embodiments shown in FIG. 2, a first terminal of the second switch Q2 is connected to a first terminal of the fourth resistor R4, a second terminal of the fourth resistor R4 is connected to a positive electrode of the second power supply DC, and the second terminal of the second switch Q2 is connected to the second terminal of the fifth resistor R5 and a negative electrode of the second power supply DC. Where at least one of a wire harness connecting the second switch Q2 with the fourth resistor R4, a wire harness connecting the fourth resistor R4 with the second power supply DC, and a wire harness connecting the second power supply DC with the second switch Q2 passes through the current transformer CT. Specifically, the second switch Q2 can be an NMOS tube, the control terminal of the second switch Q2 is the gate of the NMOS tube, the first terminal of the second switch Q2 is the drain of the NMOS tube, and the second terminal of the second switch Q2 is the source of the NMOS tube. If the output terminal of the operational amplifier U2 outputs a high level, the second switch Q2 is turned on, and the first current path generates a current signal. After the current signal passes through the current transformer CT, the current transformer CT generates an induced current. If the current transformer CT is connected to the detection circuit, the subsequent detection circuit can perform arc self-detection based on the induced current. If the output terminal of the operational amplifier U2 outputs a low level, the second switch Q2 is turned off. In practical applications, the setting methods of the first current path can be set according to actual needs, and the second switch Q2 can also use other suitable switching apparatus, and there is no need to limit to the definitions in these embodiments.

In these embodiments, by providing the current conversion branch 50, the voltage signal output by the Wien bridge oscillator circuit can be converted into a current signal, and the converted current signal can be input to the corresponding detection circuit for arc detection. Moreover, in the above method, the first current path can pass through a plurality of current transformers, so that the DC arc detection signals can be output to different detection circuits 200, and the different detection circuits 200 can complete the arc detections at the same time.

In addition, if a fault occurs in the arc detection, the DC arc detection signal can be output to the detection circuit 200 through the demultiplexer 40 and the current transformer CT. Since the current transformer CT is an off-board apparatus, if the self-detection of the detection circuit 200 based on the signal output by the demultiplexer 40 is successful, and the self-detection of the detection circuit 200 based on the signal output by the current transformer CT fails, it can be determined that the current transformer CT is faulty, that is, an off-board fault. If the self-detection of the detection circuit 200 based on the signals output by the demultiplexer 40 and the current transformer CT both fail, it can be determined that there is an on-board fault. It can be seen that in these embodiments, when the self-detection function fails, two self-detection methods are combined to determine whether there is an on-board fault or an off-board fault.

In a second aspect, embodiments of this application also provide a DC arc detection device, including the detection circuit 200 and the DC arc signal generation circuit 100 described in any one of the first aspects. The DC arc signal generation circuit 100 is connected to the detection circuit 200; the detection circuit 200 is configured to detect the DC arc in response to the electrical signal output by the DC arc signal generation circuit 100.

In these embodiments, the DC arc signal generation circuit 100 has the same structure and function as the DC arc signal generation circuit 100 described in any one of the first aspects, and will not be described here. The detection circuit can perform self-detection based on the DC arc detection signal output by the DC arc signal generation circuit 100, so that the DC arc detection device has a self-detection function.

In some embodiments, referring to FIG. 3, the detection circuit 200 includes a signal amplifying unit 210, a filtering unit 220 and a signal processing unit 230. The signal amplifying unit 210 is connected to the demultiplexer, or the signal amplifying unit 210 is connected to the current conversion branch 50. The filtering unit 220 is connected to the signal amplifying unit 210, and the signal processing unit 230 is connected to the filtering unit 220.

Specifically, if the first switch Q1 and/or the key switch SW1 are turned on, the first power supply VCC outputs electric energy to the Wien bridge oscillator circuit 20 through the OR gate U1, and the Wien bridge oscillator circuit 20 will generate disturbance components containing multiple frequencies when power is turned on. Different frequency components are amplified by the operational amplifier U2, then reduced by the frequency selection network, and cycled in sequence, so that the components of a specific frequency can oscillate stably, that is, signals at a specific frequency neither will be saturated and distorted due to the continuous amplification of the amplifier, nor will eventually disappear due to too strong attenuation. Then, the DC arc detection signal can be output to the signal amplifying unit 210 through the demultiplexer 40, and/or, the signal can be output to the signal amplifying unit 210 through the current transformer CT in the current conversion branch 50. Then, the signal amplifying unit 210 amplifies the signal and outputs it to the filtering unit 220 to ensure that the amplified signal can be output to the subsequent circuit without distortion and without adding additional frequencies. Then, the filtering unit 220 filters the signal and outputs it to the signal processing unit 230, which can filter the signal outside the non-DC arc frequency domain and output it to the signal processing unit 230. Finally, the signal processing unit 230 determines whether the self-detection is successful or fail based on the received signal.

It can be seen that in these embodiments, the detection circuit 200 can perform self-detection work based on the DC arc detection signal generated by the DC arc signal generation circuit 100. The specific circuit structure of the signal amplifying unit 210, the filtering unit 220 and the signal processing unit 230 can refer to the prior art and is not limited here.

In a third aspect, embodiments of this application provide an electrical device, which includes the DC arc detection device described in any one of the second aspects. The electrical apparatus can be photovoltaic inverters and other equipment. In these embodiments, the DC arc detection device has the same structure and function as the DC arc detection device described in any embodiment of the second aspect, and will not be described again. In these embodiments, the DC arc signal generation circuit can output a DC arc detection signal to the detection circuit, and so that the electrical equipment has a self-detection function.

It should be noted that the apparatus embodiments described above are only illustrative. The units described as separate components may or may not be physically separate. The components shown as units may or may not be physically separate, and can be located in one place or distributed across multiple network units. Some or all of the modules can be selected according to actual needs to achieve the purpose of the solution of this embodiment.

Finally, it is hereby noted that the foregoing embodiments are merely intended to illustrate technical solutions of this application rather than to limit this application; under the thought of this application, technical features in the foregoing embodiments or different embodiments may also be combined, steps may be implemented in any orders, and there are many other changes in different aspects of this application as described above, which are not provided in detail for the sake of brevity; although this application is illustrated in detail with reference to the foregoing embodiments, a person of ordinary skill in the art understands that he may still make modifications to the technical solutions recited in the foregoing embodiments or make equivalent replacements to some of the technical features; however, these modifications or replacements do not make the essence of the corresponding technical solution depart from the scope of the technical solutions of the embodiments.

What is claimed is:

1. A DC arc signal generation circuit, comprising: a first power supply, a first switch unit, and a Wien bridge oscillator circuit; the Wien bridge oscillator circuit comprises an operational amplifier;
wherein, the first power supply is electrically connected to a positive input terminal and a power supply terminal of the operational amplifier respectively through the first switch unit; and
the Wien bridge oscillator circuit is configured to output a DC arc detection signal in response to turn-on of the first switch unit.

2. The DC arc signal generation circuit according to claim 1, wherein,
the DC arc signal generation circuit further comprises a controller, and the first switch unit comprises a first resistor and a first switch;
a first terminal of the first resistor is connected to the controller and a first terminal of the first switch respectively, and a second terminal of the first resistor is connected to the first power supply and a second terminal of the first switch respectively, and a third terminal of the first switch is connected to the Wien bridge oscillator circuit.

3. The DC arc signal generation circuit according to claim 1, wherein,
the first switch unit comprises a key switch, a first terminal of the key switch is connected to the first power supply, and a second terminal of the key switch is connected to the Wien bridge oscillator circuit.

4. The DC arc signal generation circuit according to claim 1, wherein the DC arc signal generation circuit further comprises a controller;
the first switch unit comprises a first resistor, a first switch, a key switch and an OR gate;
a first terminal of the first resistor is connected to the controller and a first terminal of the first switch respectively, and a second terminal of the first resistor is connected to the first power supply and a second terminal of the first switch respectively, and a third terminal of the first switch is connected to a second input terminal of the OR gate;
a first terminal of the key switch is connected to the first power supply, and a second terminal of the key switch is connected to a first input terminal of the OR gate;
an output terminal of the OR gate is connected to the Wien bridge oscillator circuit.

5. The DC arc signal generation circuit according to claim 1, wherein the Wien bridge oscillator circuit comprises a frequency selection network and a second resistor, and the frequency selection network comprises a third resistor and a first capacitor;
a first terminal of the second resistor is connected to the first switch unit; and a second terminal of the second resistor is connected to a first terminal of the third resistor, a first terminal of the first capacitor, and a positive input terminal of the operational amplifier respectively; and
the third resistor is connected in parallel with the first capacitor, and a second terminal of the third resistor is connected to a second terminal of the first capacitor and then grounded.

6. The DC arc signal generation circuit according to claim 1, wherein the DC arc signal generation circuit further comprises a demultiplexer; and
an output terminal of the Wien bridge oscillator circuit is connected to the demultiplexer.

7. The DC arc signal generation circuit according to claim 6, wherein the DC arc signal generation circuit further comprises a current conversion branch;
the current conversion branch comprises a second switch unit, and the output terminal of the Wien bridge oscillator circuit is electrically connected to the second switch unit; and
the current conversion branch is configured to output a current signal in response to turn-on of the second switch unit.

8. The DC arc signal generation circuit according to claim 7, wherein the current conversion branch comprises a second switch, a fourth resistor, a fifth resistor, a current transformer and a second power supply;
the current conversion branch provides a first current path; the second switch, the fourth resistor, and the second power supply are part of the first current path; and the first current path passes through the current transformer; and
a first terminal of the fifth resistor is connected to an output terminal of the operational amplifier and a control terminal of the second switch respectively, and a second terminal of the second switch is connected to a second terminal of the fifth resistor and then grounded, a first terminal of the second switch is connected to a first terminal of the fourth resistor, a second terminal of the fourth resistor is connected to a positive electrode of the second power supply, a negative electrode of the second power supply is connected to the second terminal of the second switch.

9. A DC arc detection device, comprising a detection circuit and the DC arc signal generation circuit according to claim 6;
the DC arc signal generation circuit is connected to the detection circuit; and
the detection circuit is configured to detect DC arc in response to an electrical signal output by the DC arc signal generation circuit.

10. The DC arc detection device according to claim 9, wherein the DC arc signal generation circuit further comprises a current conversion branch;
the current conversion branch comprises a second switch unit, and the output terminal of the Wien bridge oscillator circuit is electrically connected to the second switch unit; and
the current conversion branch is configured to output a current signal in response to turn-on of the second switch unit.

11. The DC arc detection device according to claim 10, wherein the current conversion branch comprises a second switch, a fourth resistor, a fifth resistor, a current transformer and a second power supply;
the current conversion branch provides a first current path; the second switch, the fourth resistor, and the second power supply are part of the first current path; and the first current path passes through the current transformer; and
a first terminal of the fifth resistor is connected to an output terminal of the operational amplifier and a control terminal of the second switch respectively, and a second terminal of the second switch is connected to a second terminal of the fifth resistor and the ground, a first terminal of the second switch is connected to a first terminal of the fourth resistor, a second terminal of the fourth resistor is connected to a positive electrode of the second power supply, a negative electrode of the second power supply is connected to the second terminal of the second switch.

12. The DC arc detection device according to claim 10, wherein the detection circuit comprises a signal amplifying unit, a filtering unit and a signal processing unit;
the signal amplifying unit is connected to the demultiplexer, and/or the signal amplifying unit is connected to the current conversion branch; and
the filtering unit is connected to the signal amplifying unit, and the signal processing unit is connected to the filtering unit.

13. An electrical device, comprising the DC arc detection device according to claim 9.

14. The electrical device according to claim 13, wherein the DC arc signal generation circuit further comprises a current conversion branch;
the current conversion branch comprises a second switch unit, and the output terminal of the Wien bridge oscillator circuit is electrically connected to the second switch unit; and
the current conversion branch is configured to output a current signal in response to turn-on of the second switch unit.

15. The electrical device according to claim 14, wherein the current conversion branch comprises a second switch, a fourth resistor, a fifth resistor, a current transformer and a second power supply;
the current conversion branch provides a first current path, the second switch, the fourth resistor and the second power supply are part of the first current path; and the first current path also passes through the current transformer; and
a first terminal of the fifth resistor is connected to an output terminal of the operational amplifier and a control terminal of the second switch respectively, and a second terminal of the second switch is connected to a second terminal of the fifth resistor and then grounded, a first terminal of the second switch is connected to a first terminal of the fourth resistor, a second terminal of the fourth resistor is connected to a positive electrode of the second power supply, a negative electrode of the second power supply is connected to the second terminal of the second switch.

16. The electrical device according to claim 14, wherein the detection circuit comprises a signal amplifying unit, a filtering unit and a signal processing unit;
the signal amplifying unit is connected to the demultiplexer, and/or the signal amplifying unit is connected to the current conversion branch; and
the filtering unit is connected to the signal amplifying unit, and the signal processing unit is connected to the filtering unit.
